(19) United States
(12) Patent Application Publication
(10) Pub. No.: US 2009/0004577 A1
(43) Pub. Date: Jan. 1, 2009

(54) MASK FOR SEMICONDUCTOR DEVICE AND MANUFACTURING METHOD THEREOF

(76) Inventor: Yeon-Ah Shim, Eumseong-gun (KR)

Correspondence Address: SHERR & VAUGHN, PLLC, 620 HERNDON PARKWAY, SUITE 200, HERNDON, VA, 20170, US

(21) Appl. No.: 12/145,993

(22) Filed: Jun. 25, 2008

(30) Foreign Application Priority Data
Jun. 25, 2007 (KR) 10-2007-0062509

(51) Int. Cl. G03F 1/00; G03B 27/42

(52) U.S. Cl. 430/5; 355/53

(57) ABSTRACT

Embodiments relate to a mask used for manufacturing a semiconductor device and a method for manufacturing the same. The mask includes a first and second region formed on a semiconductor mask. First and second mask patterns may be formed in the first and second regions and aligned at first and second intervals. One or more auxiliary patterns, which may have a width of about 10 nm to 70 nm, may be aligned adjacent to the second mask patterns. The auxiliary patterns are added to the mask so that desired patterns are achieved regardless of the type of patterns, including high-density patterns, intermediate-density patterns, isolation patterns, and asymmetrical patterns.

The present application claims priority under 35 U.S.C. 119 to Korean Patent Application No. 10-2007-0062509 (filed on Jun. 25, 2007), which is hereby incorporated by reference in its entirety.

### BACKGROUND

A photolithography process is an essential process for manufacturing a semiconductor device. In a photolithography process, after uniformly coating a photoresist layer on a wafer, the wafer is subject to an exposure process by using a photomask having a predetermined layout. Then the exposed photoresist layer is developed, thereby forming a pattern having a predetermined shape.

In a semiconductor photolithography technology used for manufacturing the semiconductor device, a mask can be precisely designed such that the amount of light passing through the mask may be precisely controlled. Toward this end, OPC (optical proximity correction) technology and PSM (phase shifting mask) technology have been suggested. In addition, various methods have been proposed to minimize distortion of light caused by mask patterns.

### SUMMARY

The embodiment provides a mask for a semiconductor device capable of realizing desired patterns suitable for a semiconductor manufacturing process regardless of density of patterns formed on the mask and a method of manufacturing the same.

According to embodiments, the mask used for manufacturing the semiconductor device includes a first and second region formed on a semiconductor mask. First and second mask patterns may be formed in the first and second regions and aligned at first and second intervals. One or more auxiliary patterns, which may have a width of about 10 nm to 70 nm, may be aligned adjacent to the second mask patterns.

Embodiments include a method of manufacturing the mask for the semiconductor device. The method includes the steps of forming first mask patterns on a first region of a mask substrate at a first interval, forming second mask patterns on a second region of the mask substrate at a second interval which is larger than the first interval, and forming at least one auxiliary pattern having a width of 10 nm to 70 nm adjacent to the second mask patterns.

According to embodiments, auxiliary patterns are added to the mask, so that desired patterns can be formed on the mask regardless of the type of patterns formed on the mask, including high-density patterns, intermediate-density patterns, isolation patterns and asymmetrical patterns. According to embodiments, the mask may provide superior characteristics against process variation when forming a pattern using the mask.

According to embodiments, the depth of focus of the isolation patterns and the intermediate-density patterns can be improved by 0.1 μm or more, so that the depth of focus of the isolation patterns and the intermediate-density patterns may approximate the depth of focus of the high-density patterns. Thus, 130 nm-level or 90 nm-level semiconductor devices can be obtained through a KrF (krypton fluoride) process.

### DRAWINGS

Example FIG. 1 is a plan view showing patterns formed by using a mask according to embodiments;

Example FIG. 2 is a plan view showing mask patterns for forming the patterns shown in FIG. 1;

FIGS. 3 to 5 are graphs showing the depth of focus and CD values when the mask according to embodiments is not employed;

Example FIGS. 6 and 7 are graphs showing the depth of focus and CD values when the mask according to embodiments is employed; and

Example FIG. 8 is a graph showing aerial image intensity according to a size of an auxiliary pattern of a mask according to embodiments.

### DESCRIPTION

Hereinafter, a mask and a manufacturing method thereof according to embodiments will be described with reference to the accompanying drawings. Example FIG. 1 is a plan view showing patterns formed by using a mask according to embodiments, and example FIG. 2 is a plan view showing mask patterns for forming the patterns shown in example FIG. 1.

As shown in example FIG. 1, several groups of patterns 101, 102, 103, and 104 may be formed by a mask. The patterns 101, 102, 103, and 104 may be shallow trench isolation patterns of a semiconductor substrate, gate lines or metal interconnections.

The patterns 101, 102, 103, and 104 include first patterns 101 formed in a first region A, second patterns 102 formed in a second region B, a third pattern 103 formed in a third region C, and fourth patterns 104 formed in a fourth region D.

The first region A includes aligned patterns 101 occupying the region in a high density. For instance, if the pattern 101 has a width of 130 nm and the space between two patterns 101 is 180 nm, it is called a “dense line”. The third region C is an exemplary region which includes only the third pattern 103. No other patterns exist in the vicinity of the third pattern 103, so the third region C has a relatively large space left undeveloped. The second region B includes the aligned second patterns 102 occupying the region in an intermediate density. The density of the second patterns 102 is lower than the density of the first patterns 101, but the second patterns 102 are not isolated like the third pattern 103. The fourth region D includes asymmetrically aligned fourth patterns 104. The fourth patterns 104 may be aligned at high-density or intermediate-density. In addition, the fourth patterns 104 may include an isolation pattern.

A photoresist pattern must be formed in order to form the first to fourth patterns 101, 102, 103 and 104. This is because the first to fourth patterns 101, 102, 103 and 104 may be formed by etching a target layer using the photoresist pattern. To form the photoresist pattern, light is selectively irradiated onto a photoresist layer by using a mask 100.

As shown in example FIG. 2, the mask 100 includes a first mask region E for forming the first region A, a second mask region F for forming the second region B, a third mask region G for forming the third region C, and a fourth mask region H for forming the fourth region D. The mask 100 may include a phase shift mask having light transmittance of about 2 to 10%.

The first mask region E includes first mask patterns 111 corresponding to the first patterns 101. The first mask patterns 111 are aligned in high density. The second mask region F includes second mask patterns 112 corresponding to the second patterns 102. The second mask patterns 112 are aligned in intermediate density. The third mask region G includes a third mask pattern 113 corresponding to the third pattern 103. The third mask pattern 113 may be isolated from other mask patterns. The fourth mask region H includes fourth mask patterns 114 corresponding to the fourth patterns 104. The fourth mask patterns 114 are asymmetrically aligned in the fourth mask region H.

Auxiliary patterns 121 are provided in the vicinity of the second and third mask patterns 112 and 113. In addition, the auxiliary pattern 121 is formed in the vicinity of the fourth mask patterns 114, which are aligned at intermediate density or isolated. The auxiliary pattern 121 may have a width in a range of 10 to 70 nm. Alternatively, the auxiliary pattern 121 may have a width in a range of 20 to 60 nm. The auxiliary pattern 121 may alternatively have a width in a range of 30 to 40 nm.

The auxiliary pattern may be spaced apart from both lateral sides of the second and third mask patterns by a predetermined distance. A distance between both lateral sides of the second mask pattern and the auxiliary patterns may be different from a distance between both lateral sides of the third mask pattern and the auxiliary patterns. The auxiliary patterns 121 may be aligned parallel to the first to fourth mask patterns 111, 112, 113 and 114. In addition, the auxiliary patterns 121 may form a long line pattern together with the first to fourth mask patterns 111, 112, 113 and 114. The first to fourth mask patterns 111, 112, 113 and 114 and the auxiliary patterns 121 may include hole patterns.

When forming various patterns by using the mask 100, for example, high-density patterns, intermediate-density patterns, isolation patterns, and asymmetrical patterns, it is necessary to determine the depth of focus of the light irradiated onto the mask. If the depth of focus of the light irradiated onto the mask 100 is set to a level suitable for forming the desired high-density patterns, the intermediate-density patterns, isolation patterns, and asymmetrical patterns may not be formed with desired CD (critical dimension) even if the patterns have the same size. That is, the depth of focus of the light irradiated onto the mask 100 may vary depending on the density of the patterns.

Accordingly, in order to allow the first to fourth patterns 101 to 104 to have desired CD, the auxiliary patterns 121 are properly added to the second, third and fourth mask patterns 112, 113, and 114 when forming the mask 100, thereby uniformly maintaining the depth of focus of the light passing through the first to fourth mask patterns 111, 112, 113 and 114. The desired result may not be achieved if the size of the auxiliary pattern 121 is too large or small. For instance, if the size of the auxiliary pattern 121 is too large, undesired patterns may result in the photoresist etchings.

In order to optimize the size of the auxiliary pattern 121, an experiment has been performed. The experiment was performed by using KrF equipment generating a laser beam having a wavelength (λ) of 248 nm. The lens has an NA (numerical aperture) of 0.7 and the sigma of the light source is 0.85/0.55 (annular). The design rule of the high-density pattern was set to 110 nm/150 nm (line/space), the design rule of the intermediate-density pattern was set to 110 nm/500 nm, the design rule of the isolation pattern was set to 110 nm, and the design rule of the asymmetrical pattern was set to 116 nm/134 nm, which is identical to the design rule of a gate of a 90 nm-level flash memory. In addition, a phase shift mask with a light transmittance of 6% was used.

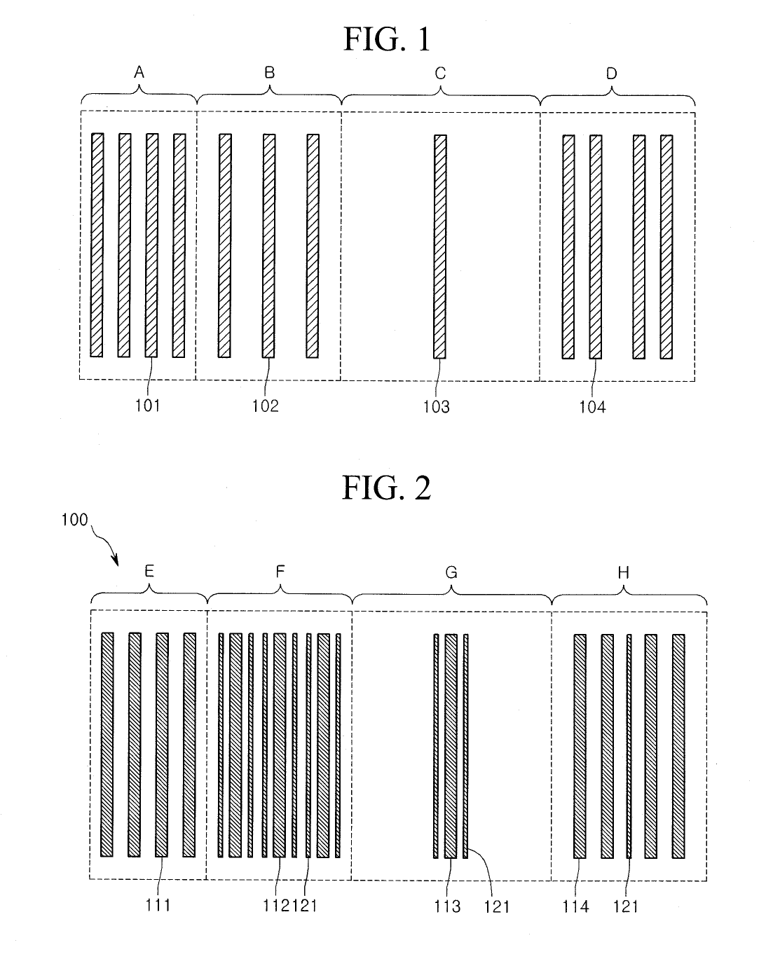

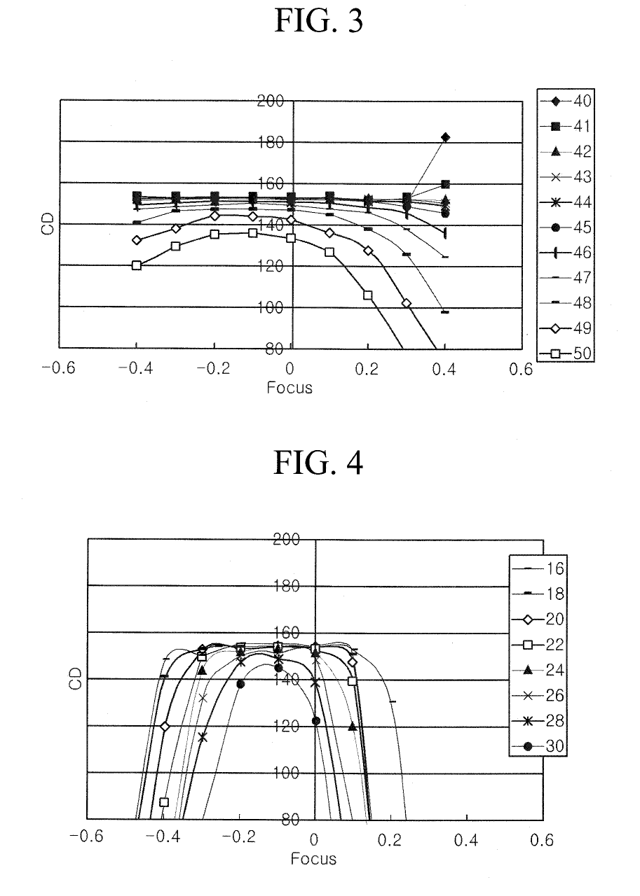

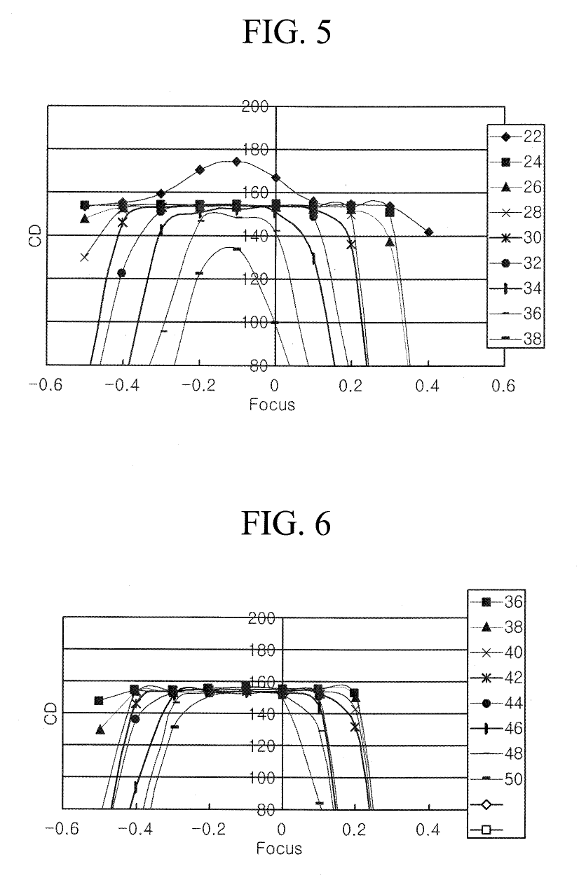

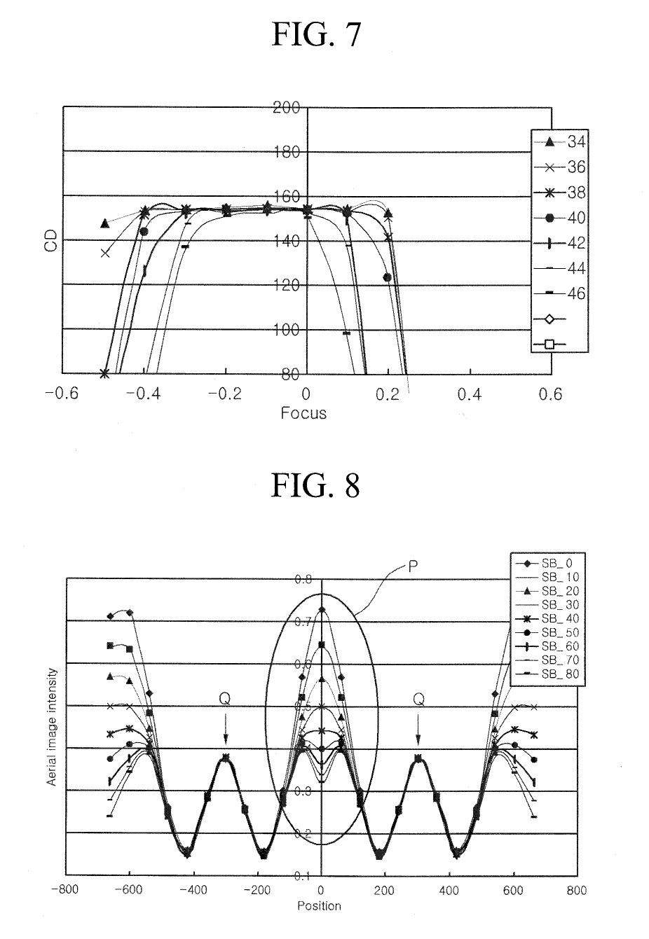

FIGS. 3 to 5 are graphs showing the depth of focus and CD values when the mask according to embodiments is not employed and example FIGS. 6 and 7 are graphs showing the depth of focus and CD values when the mask according to embodiments is employed. FIG. 3 represents a Bossung curve of the high-density patterns having no auxiliary patterns, FIG. 4 represents a Bossung curve of the intermediate-density patterns having no auxiliary patterns, and FIG. 5 represents a Bossung curve of the isolation pattern having no auxiliary patterns.

As shown in FIGS. 3 to 5, the high-density patterns have a sufficient focus depth margin of about 0.5 μm or more, but the intermediate-density patterns have a focus depth margin of about 0.3 μm, and the isolation pattern has a focus depth margin of about 0.2 μm. That is, since the mask pattern and the depth of focus of the light are set suitably for the high-density patterns, the focus depth margin of the intermediate-density patterns and the isolation pattern may be relatively reduced even if the patterns have the same size. If the mask is shaken or the depth of focus of the light is seriously varied during the process due to process variations, the intermediate-density patterns or the isolation pattern with small margins may cause pattern defects, although the high-density patterns with a sufficient margin may be properly formed.

Example FIG. 6 represents a Bossung curve of the intermediate-density patterns employing auxiliary patterns according to embodiments, and example FIG. 7 represents a Bossung curve of the isolation pattern employing auxiliary patterns according to embodiments. The auxiliary pattern in this example has a width of 30 nm. As shown in example FIGS. 6 and 7, when the auxiliary patterns are formed in the mask, the focus depth margin is increased.

The term “depth of focus” refers to the depth of focus of the light measured from a top surface of a photoresist layer. The term “focus depth margin” refers to difference between a maximum depth of focus and a minimum depth of focus that allows the formation of the desired photoresist pattern even if the depth of focus in the photoresist layer is varied due to a process variation or shaking of the mask.

In detail, the focus depth margin of the intermediate-density patterns is increased from about 0.3 μm to about 0.4 μm, and the focus depth margin of the isolation pattern is increased from about 0.2 μm to about 0.4 μm, Therefore, if the mask according to embodiments is employed in the manufacturing process for semiconductor devices, desired patterns can be formed regardless of the density of the patterns even if process variations or mask shaking occurs during the manufacturing process.

Example FIG. 8 is a graph showing aerial image intensity related to size of the auxiliary pattern of the mask according to embodiments. The graph exhibits aerial image intensity for the mask used to form the intermediate-density patterns. In example FIG. 8, the intensity is observed along various positions of the mask while varying the width of the auxiliary pattern from 0 nm to 80 nm at an interval of 10 nm.

Curve SB_0 represents an auxiliary pattern with a width of 0 nm. Curve SB_10 represents an auxiliary pattern with a width of 10 nm. Curve SB_20 represents an auxiliary pattern with a width of 20 nm. Curve SB_30 represents an auxiliary pattern with a width of 30 nm. Curve SB_40 represents an auxiliary pattern with a width of 40 nm. Curve SB_50 represents an auxiliary pattern with a width of 50 nm. Curve SB_60 represents an auxiliary pattern with a width of 60 nm. Curve SB_70 represents an auxiliary pattern with a width of 70 nm. Curve SB_80 represents an auxiliary pattern with a width of 80 nm.

As shown at the P position and the Q positions of example FIG. 8, if the auxiliary pattern has a width of 70 nm or above, the intensity of light passing through the auxiliary pattern becomes similar to that of light passing through the intermediate-density pattern, so that the pattern is formed based on the auxiliary pattern. The pattern formed based on the auxiliary pattern is an undesirable pattern, causing defects in the semiconductor device.

As shown at the P position and the Q positions of example FIG. 8, if the auxiliary pattern has a width in the range of 20 to 60 nm, the aerial image is changed approximately to the high-density pattern. That is, the depth of focus of light in the intermediate-density pattern becomes similar to the depth of focus of light in the high-density pattern. Therefore, if the mask having the auxiliary patterns according to embodiments is employed, the depth of focus of the intermediate-density pattern and the isolation pattern can be adjusted even if the mask and the illumination conditions are set most suitably for the high-density patterns.

Accordingly, the depth of focus of the mask can be properly adjusted by adding the auxiliary patterns to the intermediate-pattern, the isolation pattern, and the asymmetrical pattern when forming the mask, so that desired patterns can be obtained regardless of the density of the patterns. According to embodiments, the depth of focus of the isolation patterns and the intermediate-density patterns can be improved by 0.1 μm or more, so that the depth of focus of the isolation patterns and the intermediate-density patterns may approximate to the depth of focus of the high-density patterns. Thus, 130 nm-level or 90 nm-level semiconductor devices can be obtained using KrF equipment.

According to embodiments, resolution of the KrF equipment can be improved by modifying the design of the mask. According to embodiments, auxiliary patterns are added to the mask, so that desired patterns can be formed on the mask regardless of the type of patterns formed on the mask, including high-density patterns, intermediate-density patterns, isolation patterns and asymmetrical patterns. According to embodiments, the mask may provide superior characteristics against process variations when forming a pattern using the mask.

According to embodiments, the depth of focus of the isolation patterns and the intermediate-density patterns can be improved by 0.1 μm or more, so that the depth of focus of the isolation patterns and the intermediate-density patterns may approximate to the depth of focus of the high-density patterns. Thus, 130 nm-level or 90 nm-level semiconductor devices can be obtained through a KrF process.

It will be obvious and apparent to those skilled in the art that various modifications and variations can be made in embodiments disclosed. Thus, it is intended that the disclosed embodiments cover the obvious and apparent modifications and variations, provided that they are within the scope of the appended claims and their equivalents.

What is claimed is:

1. An apparatus comprising:
a first region formed on a semiconductor mask;
a second region formed on a semiconductor mask;
first mask patterns formed in the first region and aligned at a first interval;
second mask patterns formed in the second region and aligned at a second interval which is larger than the first interval; and
at least one auxiliary pattern aligned adjacent to the second mask patterns, wherein the mask is used in a selective exposure process performed on a photoresist layer formed on a semiconductor substrate, a photoresist pattern is formed corresponding to the first and second mask patterns, and the photoresist pattern is not substantially formed at a location corresponding to the auxiliary pattern.

2. The apparatus of claim 1, wherein the first and second mask patterns have a width in a range between 90 nm to 130 nm.

3. The apparatus of claim 1, wherein the auxiliary pattern has a width of about 10 nm to 70 nm.

4. The apparatus of claim 1, wherein the auxiliary pattern has a width in a range between 20 nm to 60 nm.

5. The apparatus of claim 1, wherein the auxiliary pattern has a width in a range between 30 nm to 40 nm.

6. The apparatus of claim 1, wherein the second mask patterns include an isolation pattern.

7. The apparatus of claim 1, wherein the mask is used with KrF equipment.

8. The apparatus of claim 1, wherein the mask includes a phase shift mask having light transmittance of 2 to 10%.

9. The apparatus of claim 1, wherein the first mask pattern, the second mask pattern and the auxiliary pattern are aligned parallel to each other.

10. The apparatus of claim 1, wherein a depth of focus of light passing through the first mask pattern is substantially the same as a depth of focus of light passing through the second mask pattern.

11. The apparatus of claim 1, wherein the first and second mask patterns and the auxiliary pattern include hole patterns for transmitting light.

12. The apparatus of claim 1, wherein the auxiliary pattern is spaced part from both lateral sides of the second mask patterns by a predetermined distance.

13. A method comprising:
forming first mask patterns on a first region of a mask substrate at a first interval;
forming second mask patterns on a second region of the mask substrate at a second interval which is larger than the first interval; and
forming at least one auxiliary pattern, wherein the mask is used in a selective exposure process performed on a photoresist layer formed on a semiconductor substrate, a photoresist pattern is formed corresponding to the first and second mask patterns, and the photoresist pattern is not substantially formed at a location corresponding to the auxiliary pattern.

14. The method of claim 13, wherein the first and second mask patterns and the auxiliary pattern include hole patterns for transmitting light.

15. The method of claim 13, wherein the auxiliary pattern is spaced part from both lateral sides of the second mask patterns by a predetermined distance.

16. The method of claim 13, wherein the first and second mask patterns have a width in a range between 90 nm to 130 nm.

17. The method of claim 13, wherein the auxiliary pattern has a width of about 10 nm to 70 nm.

18. The method of claim 13, wherein the auxiliary pattern has a width in a range between 20 nm to 60 nm.

19. The method of claim 13, wherein the auxiliary pattern has a width in a range between 30 nm to 40 nm.

20. The method of claim 13, wherein the mask is used with KrF equipment.
